(19) United States
(12) Patent Application Publication
(10) Pub. No.: US 2025/0113561 A1
(43) Pub. Date: Apr. 3, 2025

(54) STACKED TRANSISTORS WITH STRAIN MATERIALS ON SOURCE AND DRAIN

(71) Applicant: Intel Corporation, Santa Clara, CA (US)

(72) Inventors: Rahul Ramaswamy, Portland, OR (US); Marko Radosavljevic, Portland, OR (US); Hsu-Yu Chang, Hillsboro, OR (US); Scott M. Mokler, Hillsboro, OR (US); Stephanie Chin, Portland, OR (US); Walid M. Hafez, Portland, OR (US)

(73) Assignee: Intel Corporation, Santa Clara, CA (US)

(21) Appl. No.: 18/476,624

(22) Filed: Sep. 28, 2023

(51) Int. Cl. H01L 29/06; H01L 27/092; H01L 29/423; H01L 29/778; H01L 29/78; H01L 29/786

(52) U.S. Cl. CPC H10D 62/116; H10D 30/47; H10D 30/6211; H10D 30/6735; H10D 30/6757; H10D 62/118; H10D 84/853

(57) ABSTRACT

In stacked transistor device, such as a complementary field-effect-transistor (CFET) device, different strain materials may be used in different layers, e.g., a tensile material is deposited in a first isolation region in the PMOS layer, and a compressive material is deposited in second isolation region in the NMOS layer. The strain materials may be stacked, such that the second isolation region may be positioned over the first isolation region. In some cases, in one or both of the isolation regions, a liner material is included between the strain material and the source and drain regions. Certain embodiments provide independent tuning of strain forces in a stacked transistor device. Different materials are selected for different layers in the stacked device to provide favorable performance enhancement or tuning (e.g., adjustment of the threshold voltage) in NMOS and PMOS layers.

### BACKGROUND

Integrated circuit devices typically include a device layer in which transistors are formed. In certain architectures, some transistors in the device layer are P-type metal oxide semiconductor (PMOS) transistors, and other transistors are N-type metal oxide semiconductor (NMOS) transistors. In a complementary field-effect-transistor (CFET) device, NMOS devices and PMOS devices are stacked on top of each other. For example, a layer of NMOS devices is stacked over a layer of PMOS devices, or vice versa. The CFET architecture can help with scaling the height of the standard transistor cell in the device.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a schematic illustration of a cross-sectional view of an example transistor, according to some embodiments of the present disclosure.

FIGS. 2A-2C illustrate different cross-sections through several transistors in a CFET device, according to some embodiments of the present disclosure.

FIGS. 3A-3C illustrate cross-sections through a first example CFET device having different strain materials in different layers, according to some embodiments of the present disclosure.

FIG. 4 illustrates a cross-section of a second example CFET device having different strain materials in different layers, according to some embodiments of the present disclosure.

FIG. 5 illustrates a cross-section of a third example CFET device having different strain materials in different layers, according to some embodiments of the present disclosure.

FIGS. 6A and 6B are top views of, respectively, a wafer and dies that may include stacked transistors and strain materials as described herein in accordance with any of the embodiments disclosed herein.

FIG. 7 is a cross-sectional side view of an IC package that may include stacked transistors and strain materials as described herein in accordance with any of the embodiments disclosed herein.

FIG. 8 is a cross-sectional side view of an IC device assembly that may include stacked transistors and strain materials as described herein in accordance with any of the embodiments disclosed herein.

FIG. 9 is a block diagram of an example computing device that may include stacked transistors and strain materials as described herein in accordance with any of the embodiments disclosed herein.

### DETAILED DESCRIPTION

### Overview

In various transistors, such as FinFETs and gate-all-around transistors, strain materials can be placed in regions between transistors, e.g., to apply a tensile or compressive strain on a source or drain region. For example, during fabrication of a FinFET, fin-shaped structures are formed from a semiconductor, e.g., by etching portions of a silicon wafer. The fin-shaped structures may be long regions that are then isolated by a fin trim isolation (FTI) process, where the FTI process etches portions of the fin-shaped structures to form individuated fin structures, and transistors may be formed around the individuated fins. In particular, the fins form semiconductor channels, and a gate stack, a source region, and a drain region may be formed around each of the fin-shaped channels, realizing a FinFET.

After individuating the channels for different transistors, a dielectric material may be deposited between adjacent fins to provide electrical isolation and physical support. In some cases, the dielectric material deposited between adjacent transistors (e.g., adjacent fins or adjacent nanoribbon stacks) is a dielectric material that can apply a particular type of stress or strain to adjacent materials, and in particular, to source and/or drain regions formed around the channels and on either side of the dielectric material. Using a strain material can improve transistor performance, e.g., shifting the threshold voltage on the source and/or the drain and/or controlling the short-channel effect.

A particular strain material may impart different effects on PMOS and NMOS devices. For example, if a material that provides a tensile strain is adjacent to the source and drain regions of both NMOS and PMOS devices, the PMOS performance is improved, but the NMOS performance may be degraded. Conversely, if a material that provides a compressive strain is adjacent to the source and drain regions of both NMOS and PMOS devices, the NMOS performance is improved, but the PMOS performance may be degraded. Thus, when NMOS and PMOS devices are in a single layer, using a single isolation material in the fin trim isolation regions provides non-ideal results, where some transistors have improved performance while others may be negatively affected. Achieving performance improvement in both NMOS and PMOS devices in a single layer using strain materials involves two deposition processes with different materials, and lithography to block NMOS or PMOS devices during the deposition processes.

A CFET is a type of transistor configuration that combines both N-channel and P-channel field-effect transistors (FETs) within the same circuit. This design allows for efficient digital and analog circuitry, especially in complementary metal-oxide-semiconductor (CMOS) technology. In a CFET arrangement, the N-channel FET may operate as an enhancement mode transistor, while the P-channel FET may operate as a depletion mode transistor. When used together, these transistors complement each other's behavior. CFETs may be employed in digital logic gates, memory cells, and various integrated circuits (ICs). The complementary nature of CFETs may reduce power consumption and/or enhance overall circuit performance in modern electronic devices.

When a CFET architecture is used, a layer of NMOS devices may be stacked over a layer of PMOS devices, or vice versa. The CFET transistors may have a non-planar transistor architecture, e.g., the transistors may be FinFETs, gate all-around transistors, nanoribbon transistors, nanowire transistors, or another transistor architecture. In some cases, individual transistors may be aligned and stacked, e.g., an NMOS transistor in the NMOS layer may be stacked over a PMOS transistor in the PMOS layer. A pair of transistors (e.g., a stacked NMOS and PMOS transistor) may be coupled together in a circuit, e.g., connected in parallel or in series with each other.

As described herein, in a device that includes stacked transistors, such as transistors arranged in a CFET architecture, different strain materials may be used in different layers, e.g., a tensile material is deposited in a first FTI region in the PMOS layer, and a compressive material is deposited in second FTI region in the NMOS layer. The strain materials may be stacked, such that the second FTI region may be positioned over the first FTI region. In some cases, in one or both of the FTI regions, a liner material is included between the strain material and the source and drain regions. For example, in a given layer, a liner dielectric material is deposited, and the strain material is deposited within the liner. Certain embodiments disclosed herein provide independent tuning of strain forces in a stacked transistor device. Different materials are selected for different layers in the stacked device to provide favorable performance enhancement or tuning (e.g., adjustment of the threshold voltage) in NMOS and PMOS layers.

In some embodiments, within a given layer, different materials can be selected to provide asymmetrical strains on sources and drains, e.g., to increase the threshold voltage at the source, and lower the threshold voltage at the drain. This may be achieved using a lithographic process that deposits different materials adjacent to sources and drains of a single device type (e.g., one strain material adjacent to the drain of a transistor, and another strain material adjacent to the source of the transistor). A higher threshold voltage on the source may improve injection velocity, while a lower threshold voltage on the drain may reduce the electric field and mitigate short-channel effects, e.g., reducing subthreshold leakage current and providing more consistent transistor behavior.

In the following, some descriptions may refer to a particular source or drain region or contact being either a source region/contact or a drain region/contact. However, unless specified otherwise, which region/contact of a transistor is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a support structure that includes electrically conductive interconnect structures for providing electrical connectivity between different IC components. Metal layers described herein may also be referred to as “interconnect layers” to clearly indicate that these layers include electrically conductive interconnect structures which may but does not have to be metal.

The systems, methods and devices of this disclosure each have several innovative aspects, no single one of which is solely responsible for the all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. As used herein, a “logic state” (or, alternatively, a “state” or a “bit” value) of a memory cell may refer to one of a finite number of states that the cell can have, e.g., logic states “1” and “0,” each state represented by a different voltage of the capacitor of the cell, while “READ” and “WRITE” memory access or operations refer to, respectively, determining/sensing a logic state of a memory cell and programming/setting a logic state of a memory cell. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

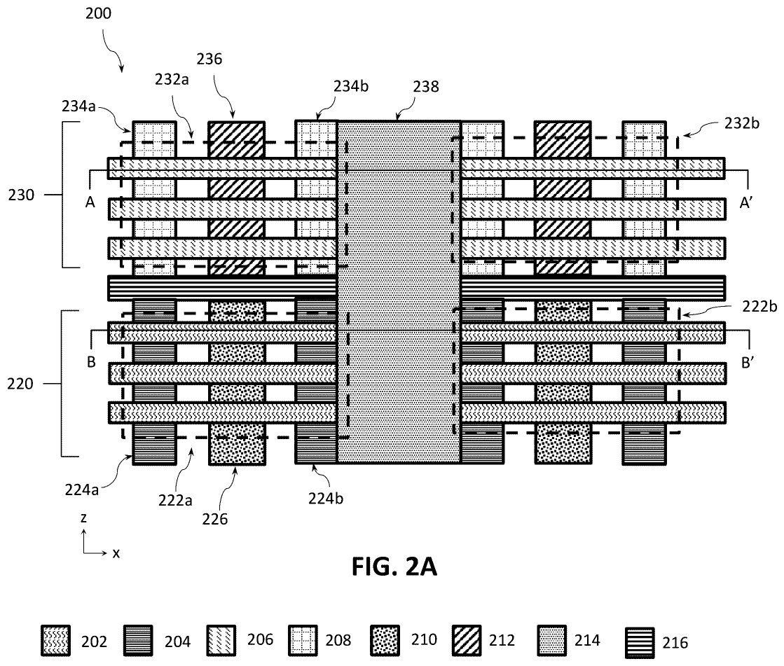

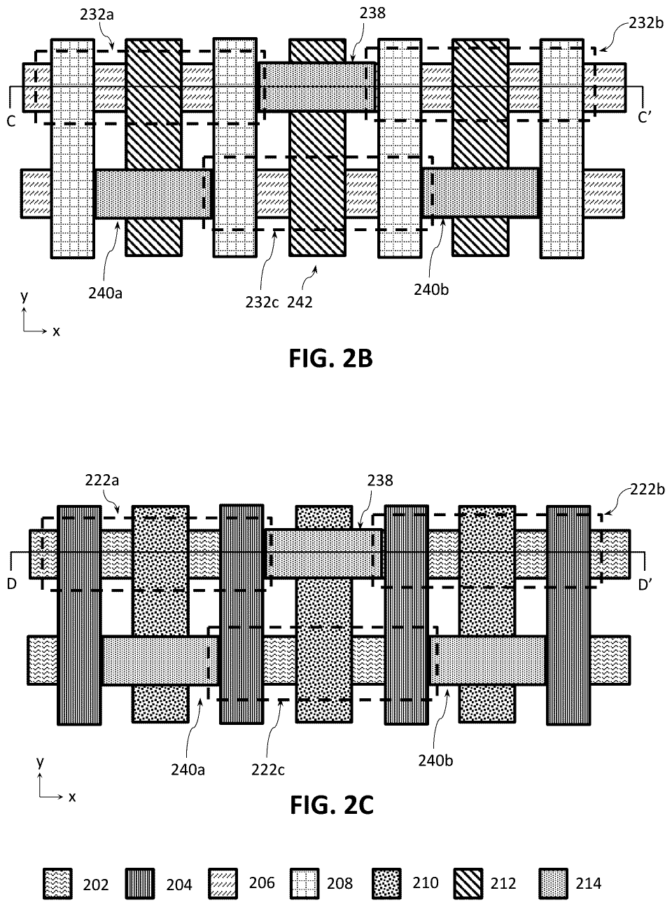

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 2A-2C, such a collection may be referred to herein without the letters, e.g., as “FIG. 2.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with stacked transistors and strain materials as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

### Example Transistor Arrangement

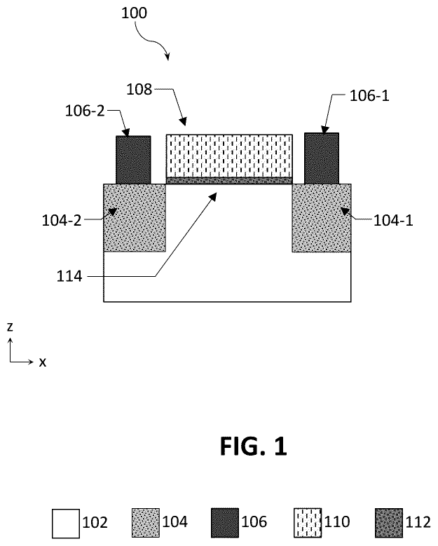

FIG. 1 provides a schematic illustration of a cross-sectional view of an example transistor 100, according to some embodiments of the present disclosure. The transistor 100 may be included in an IC device, e.g., in the stacked transistor devices described herein. The transistor 100 may be included in various regions/locations in an IC device. For example, the transistor 100 may be used as, e.g., a logic transistor in a compute logic device. In another example, the transistor 100 may be used as, e.g., an access transistor in a memory device.

A number of elements labeled in FIG. 1 are illustrated in this figure with different patterns, with a legend showing the correspondence between the reference numerals and patterns being provided at the bottom of the drawing page containing FIG. 1. For example, the legend illustrates that FIG. 1 uses different patterns to show a channel material 102, source or drain (“S/D”) regions 104, contacts 106 to S/D regions, a gate electrode 110, and a gate dielectric 112. The view shown in FIG. 1 is intended to show relative arrangements of various elements therein, and various IC devices, or portions thereof, may include other elements or components that are not illustrated (e.g., any further materials, such as spacer materials that may surround the gate stack of the transistor 100, etch-stop materials, etc.).

In general, a FET, e.g., a metal oxide semiconductor (MOS) FET (MOSFET), is a three-terminal device that includes source, drain, and gate terminals and uses electric field to control current flowing through the device. A FET typically includes a channel material, a source region, and a drain region provided in the channel material, and a gate stack that includes a gate electrode material, alternatively referred to as a “work function” (WF) material, provided over a portion of the channel material between the source and the drain regions, and, optionally, also includes a gate dielectric material between the gate electrode material and the channel material. This general structure is shown in FIG. 1, illustrating a channel material 102, S/D regions 104 (shown as a first S/D region 104-1, e.g., a source region, and a second S/D region 104-2, e.g., a drain region), contacts 106 to S/D regions (shown as a first S/D contact 106-1, providing electrical contact to the first S/D region 104-1, and a second S/D contact 106-2, providing electrical contact to the second S/D region 104-2), and a gate stack 108, which includes at least a gate electrode 110 and may also, optionally, include a gate dielectric 112.

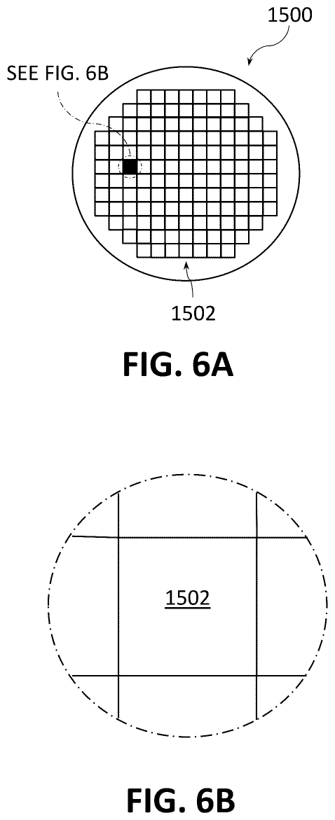

In general, implementations of the present disclosure may be formed or carried out on a support structure, e.g., a support structure under the channel material 102. The support structure (not specifically shown in FIG. 1) may be, e.g., a substrate, a die, a wafer, or a chip. For example, the support structure may be the wafer 1500 of FIG. 6A, discussed below, and may be, or be included in, a die, e.g., the singulated die 1502 of FIG. 6B, discussed below. In some embodiments, the support structure may be a substrate that includes silicon and/or hafnium. More generally, the support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the substrate may be formed are described here, any material that may serve as a foundation upon which a semiconductor device including any of the cell architectures described herein may be built falls within the spirit and scope of the present disclosure.

In some embodiments, the channel material 102 may be composed of semiconductor material systems including, for example, N-type or P-type materials systems. In some embodiments, the channel material 102 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 102 may include a combination of semiconductor materials where one semiconductor material may be used for the channel portion (e.g., a portion 114 shown in FIG. 1, which is supposed to refer to the upper-most portion of the channel material 102) and another material, sometimes referred to as a “blocking material,” may be used between the channel portion 114 and the support structure over which the transistor 100 is provided. In some embodiments, the channel material 102 may include a monocrystalline semiconductor, such as silicon (Si) or germanium (Ge). In some embodiments, the channel material 102 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistor 100 is an NMOS), the channel portion 114 of the channel material 102 may advantageously include a III-V material having a high electron mobility, such as, but not limited to InGaAs, InP, InSb, and InAs. For some such embodiments, the channel portion 114 of the channel material 102 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). In some embodiments with highest mobility, the channel portion 114 of the channel material 102 may be an intrinsic III-V material, i.e., a Ill-V semiconductor material not intentionally doped with any electrically active impurity. In alternate embodiments, a nominal impurity dopant level may be present within the channel portion 114 of the channel material 102, for example to further fine-tune a threshold voltage Vt, or to provide HALO pocket implants, etc. Even for impurity-doped embodiments however, impurity dopant level within the channel portion 114 of the channel material 102 may be relatively low, for example below 10¹⁵ dopant atoms per cubic centimeter (cm⁻³), and advantageously below 10¹³ cm⁻³.

For some example P-type transistor embodiments (i.e., for the embodiments where the transistor 100 is a PMOS), the channel portion 114 of the channel material 102 may advantageously be a group IV material having a high hole mobility, such as, but not limited to Ge or a Ge-rich SiGe alloy. For some example embodiments, the channel portion 114 of the channel material 102 may have a Ge content between 0.6 and 0.9, and advantageously may be at least 0.7. In some embodiments with highest mobility, the channel portion 114 may be intrinsic III-V (or IV for P-type devices) material and not intentionally doped with any electrically active impurity. In alternate embodiments, one or more a nominal impurity dopant level may be present within the channel portion 114, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³.

As shown in FIG. 1, a first and a second S/D region 104-1, 104-2 (together referred to as “S/D regions 104”) may be included on either side of the gate stack 108, thus realizing a transistor. As is known in the art, source and drain regions (also sometimes interchangeably referred to as “diffusion regions”) are formed for the gate stack of a FET. In some embodiments, the S/D regions 104 of the transistor 100 may be regions of doped semiconductors, e.g. regions of the channel material 102 (e.g., of the channel portion 114) are doped with a suitable dopant to a suitable dopant concentration, so as to supply charge carriers for the transistor channel. S/D regions 104 of a particular transistor type (e.g., N-type or P-type) may receive a suitable dopant, e.g., acceptor-type dopants (e.g., boron) for PMOS and donor-type dopants (e.g., arsenic or phosphorus) for NMOS. In some embodiments, the S/D regions 104 may be highly doped, e.g. with dopant concentrations of about 1·10²¹ cm⁻³, in order to advantageously form Ohmic contacts with the respective S/D contacts 106, although, in other embodiments, these regions may also have lower dopant concentrations and may form Schottky contacts in some implementations. Irrespective of the exact doping levels, the S/D regions 104 of the transistor 100 may be the regions having dopant concentration higher than in other regions, e.g., higher than a dopant concentration in a region of the channel material 102 between the first S/D region 104-1 and the second S/D region 104-2, and, therefore, may be referred to as “highly doped” (HD) regions.

In some embodiments, the S/D regions 104 may generally be formed using either an implantation/diffusion process or an etching/deposition process. In the former process, dopants such as boron, aluminum, antimony, phosphorous, or arsenic may be ion-implanted into the one or more semiconductor materials of the upper portion of the channel material 102 to form the S/D regions 104. An annealing process that activates the dopants and causes them to diffuse further into the channel material 102 may follow the ion implantation process. In the latter process, the one or more semiconductor materials of the channel material 102 may first be etched to form recesses at the locations for the future S/D regions. An epitaxial deposition process may then be carried out to fill the recesses with material (which may include a combination of different materials) that is used to fabricate the S/D regions 104. In some implementations, the S/D regions 104 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 104 may be formed using one or more alternate semiconductor materials such as germanium or a group III-V material or alloy. Although FIG. 1 illustrates the first and second S/D regions 104 with a single pattern, suggesting that the material composition of the first and second S/D regions 104 is the same, this may not be the case in some other embodiments of the transistor 100. Thus, in some embodiments, the material composition of the first S/D region 104-1 may be different from the material composition of the second S/D region 104-2.

As further shown in FIG. 1, S/D contacts 106-1 and 106-2 (together referred to as “S/D contacts 106”), which are formed of one or more electrically conductive materials, may be used for providing electrical connectivity to the S/D regions 104-1 and 104-2, respectively. In various embodiments, the electrically conductive materials of the S/D contacts 106 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the S/D contacts 106 may include one or more electrically conductive alloys, oxides, or carbides of one or more metals. In some embodiments, the S/D contacts 106 may include a doped semiconductor, such as silicon or another semiconductor doped with an N-type dopant or a P-type dopant. Metals may provide higher conductivity, while doped semiconductors may be easier to pattern during fabrication. Although FIG. 1 illustrates the first and second S/D contacts 106 with a single pattern, suggesting that the material composition of the first and second S/D contacts 106 is the same, this may not be the case in some other embodiments of the transistor 100. Thus, in some embodiments, the material composition of the first S/D contact 106-1 may be different from the material composition of the second S/D contact 106-2.

Turning to the gate stack 108, the gate electrode 110 may include at least one P-type work function metal or N-type work function metal, depending on whether the transistor 100 is a PMOS transistor or an NMOS transistor. For a PMOS transistor, metals that may be used for the gate electrode 110 may include, but are not limited to, ruthenium, palladium, platinum, cobalt, nickel, and conductive metal oxides (e.g., ruthenium oxide). For an NMOS transistor, metals that may be used for the gate electrode 110 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 110 may include a stack of two or more metal layers, where one or more metal layers are WF metal layers and at least one metal layer is a fill metal layer.

If used, the gate dielectric 112 may at least laterally surround the channel portion 114, and the gate electrode 110 may laterally surround the gate dielectric 112 such that the gate dielectric 112 is disposed between the gate electrode 110 and the channel material 102. In various embodiments, the gate dielectric 112 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 112 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 112 during manufacture of the transistor 600 to improve the quality of the gate dielectric 112. In some embodiments, the gate dielectric 112 may have a thickness between about 0.5 nanometers and 3 nanometers, including all values and ranges therein, e.g., between about 1 and 3 nanometers, or between about 1 and 2 nanometers.

In some embodiments, the gate stack 108 may be surrounded by a dielectric spacer, not specifically shown in FIG. 1. The dielectric spacer may be configured to provide separation between the gate stacks 108 of different transistors 100 which may be provided adjacent to one another (e.g., different transistors 100 provided along a single fin if the transistors 100 are FinFETs), as well as between the gate stack 108 and one of the S/D contacts 106 that is disposed on the same side as the gate stack 108. Such a dielectric spacer may include one or more low-k dielectric materials. Examples of the low-k dielectric materials that may be used as the dielectric spacer include, but are not limited to, silicon dioxide, carbon-doped oxide, silicon nitride, fused silica glass (FSG), and organosilicates such as silsesquioxane, siloxane, and organosilicate glass. Other examples of low-k dielectric materials that may be used as the dielectric spacer include organic polymers such as polyimide, polynorbornenes, benzocyclobutene, perfluorocyclobutane, or polytetrafluoroethylene (PTFE). Still other examples of low-k dielectric materials that may be used as the dielectric spacer include silicon-based polymeric dielectrics such as hydrogen silsesquioxane (HSQ) and methylsilsesquioxane (MSQ). Other examples of low-k materials that may be used in a dielectric spacer include various porous dielectric materials, such as for example porous silicon dioxide or porous carbon-doped silicon dioxide, where large voids or pores are created in a dielectric in order to reduce the overall dielectric constant of the layer, since voids can have a dielectric constant of nearly 1.

As shown in FIG. 1, the second S/D contact 106-2 is provided on the same side as the gate stack 108, which may be considered to be the front side of the transistor 100, while the first S/D contact 106-1 is provided on the opposite side, which may be considered to be the back side of the transistor 100. Thus, the first S/D contact 106-1 is the back side contact and the second S/D contact 106-2 is the front side contact of the transistor 100. In other embodiments, both S/D contacts 106 may be provided on a single side of a transistor, e.g., on the front side (where the gate stack 108 is provided) or on the back side. Further, while the gate stack 108 is provided on the front side in FIG. 1, alternatively, the gate stack 108 may be provided on the back side.

In some embodiments, the stacked transistors described herein may have non-planar architectures. Non-planar transistors are three-dimensional electronic devices that deviate from a traditional flat transistor design. Compared to planar transistors, non-planar transistors can provide improved control over current flow, reduced leakage, and enhanced performance, making it a key technology for smaller, faster, and more energy-efficient electronic devices. Examples of non-planar transistors include fin-shaped FETs, referred to as FinFETs, and gate-all-around (GAA) transistors.

For example, the transistor 100 may be a FinFET. FinFETs have a non-planar architecture where a fin, formed of one or more semiconductor materials, extends away from a base. For example, the channel material 102 may have a fin shape, and the channel portion 114 may be an upper portion of the fin. The gate stack 108, which includes the gate electrode 110 and may also, optionally, include the gate dielectric 112, is provided over the top and sides of the fin, such that the gate wraps around a portion of the fin.

In other embodiments, stacked transistor devices may include GAA transistors, also referred to as surrounding-gate transistors. GAA transistors have a gate material (e.g., the gate electrode 110 and, in some embodiments, the gate dielectric 112) that surrounds a channel region (e.g., the channel material 102) on all sides. GAA transistors may be nanoribbon-based or nanowire-based. In a nanoribbon transistor, a gate stack that may include one or more gate electrode materials and a gate dielectric may be provided around a portion of an elongated semiconductor structure called “nanoribbon”, forming the gate stack on all sides of the nanoribbon.

In both FinFETs and GAA transistors, a source region and a drain region can be provided on the opposite ends of the channel (e.g., the fin, the nanoribbon(s), or nanowire(s)) and on either side of the gate stack, forming, respectively, a source and a drain of such a transistor.

### Example CFET Architecture

FIGS. 2A-2C illustrate different cross-sections through several transistors in a CFET device 200, according to some embodiments of the present disclosure. A number of elements in FIGS. 2-5 are illustrated in these figures with different patterns, with a legend showing the correspondence between the reference numerals and patterns being provided at the bottom of each drawing page containing these figures. For example, the legend illustrates that FIGS. 2A-2C use different patterns to show a first channel material 202, a first S/D material 204, a second channel material 206, a second S/D material 208, a first gate material 210, a second gate material 212, an isolation material 214, and an oxide 216.

The cross-sections illustrated in FIG. 2A-2C show cross-sections of two transistor layers with transistors of different types. FIG. 2A illustrates a first layer 220 with transistors 222a and 222b (referred to jointly as transistors 222) and a second layer 230 with transistors 232a and 232b (referred to jointly as transistors 232). For example, the transistors 222 are PMOS transistors, and the transistors 232 are NMOS transistors. Alternatively, the transistors 222 are NMOS transistors, and the transistors 232 are PMOS transistors. The materials used within the transistors 222 and 232 are typically different, e.g., the first channel material 202, first S/D material 204, and first gate material 210 may be selected from the materials used for PMOS transistors described with respect to FIG. 1, and the second channel material 206, second S/D material 208, and second gate material 212 may be selected from the materials used for NMOS transistors described with respect to FIG. 1. While two layers 220 and 230 are illustrated, in other embodiments, a different number of layers of transistors may included in the CFET device 200.

FIG. 2B illustrates a cross-section through the first layer 220, and in particular, through the plane AA′ in FIG. 2A. FIG. 2C illustrates a cross-section through the second layer 230, and in particular, through the plane BB′ in FIG. 2A. While two transistors are illustrated in each layer, it should be understood that each layer may include many more transistors, e.g., additional transistors in the x-direction in the coordinate system shown, and transistors in the y-direction in the coordinate system shown (e.g., viewed in different x-z cross-sections). For example, FIGS. 2B and 2C illustrate an additional row of transistors in the y-direction.

The transistors 222 and 232 are GAA transistors, and in particular, are nanowire or nanoribbon transistors. The channel materials 202 and 206 are arranged as a set of three nanoribbons, where each nanoribbon has an elongated structure. The nanoribbons may extend over a support structure, e.g., a substrate or other support structure as described above. The support structure may have a face extending in the x-y plane in the coordinate system shown. Each nanoribbon extends primarily in the x-direction in the coordinate system shown, e.g., parallel to the face of the support structure. The nanoribbons also extend in a direction parallel to the other nanoribbons in the stack. The second layer 230 is over the first layer 220, and the first layer 220 is under the second layer 230. The transistors 232 are stacked over the transistors 222. The support structure may be under the first layer 220, so that the first layer 220 is over the support structure, and the second layer 230 is over the support structure and over the first layer 220.

A source region and a drain region are formed around the ends of the nanoribbon channels. For example, a first S/D region 224a (e.g., a source region) and a second S/D region 224b (e.g., a drain region) are formed around the ends of the nanoribbons of the transistor 222a. A first S/D region 234a and a second S/D region 234b are formed around the ends of the nanoribbons of the transistor 232a. Gate stacks, which may include a gate electrode and a gate dielectric between the gate electrode and the channel material 202 or 206, are formed around the nanoribbons, between the S/D regions. For example, the gate stack 226 is formed around a middle portion of the nanoribbons of the transistor 222a, and the gate stack 236 is formed around a middle portion of the nanoribbons of the transistor 232a.

A layer of oxide 216 separates the lower layer 220 from the upper layer 230. In addition, an isolation region 238 that includes the isolation material 214 is between adjacent transistors in each layer. In the first layer 220, the isolation region 238 is adjacent to and, in this case, in contact with the S/D region 224b of the transistor 222a, and the isolation region 238 is adjacent to and, in this case, in contact with another S/D region of the transistor 222b on the opposite side of the isolation material 214. In the second layer 230, the isolation region 238 is adjacent to and, in this case, in contact with the S/D region 234b of the transistor 232a, and the isolation region 238 is adjacent to and, in this case, in contact with another S/D region of the transistor 232b on the opposite side of the isolation region 238. Additional isolation regions formed from the isolation material 214 may be on the other sides of the transistors, e.g., abutting the S/D regions 224a and 234b. Additional dielectric material not specifically illustrated may be included, e.g., between S/D regions and gates.

As noted above, FIG. 2B illustrates a cross-section through the plane AA′ in FIG. 2A. FIG. 2A is the cross-section through the plane CC′ in FIG. 2B. FIG. 2B includes the transistors 232a and 232b, and the isolation region 238 between the transistors 232a and 232. FIG. 2B further includes a third transistor 232c and a pair of isolation regions 240a and 240b on either side of the transistor 232c. The isolation regions 240a and 240b are similar to the isolation region 238. Each of the isolation regions 238, 240a, and 240b are generally through a portion of a gate line, e.g., the isolation region 238 is along the gate line 242.

FIG. 2C illustrates a cross-section through the plane BB′ in FIG. 2A. FIG. 2A is the cross-section through the plane DD′ in FIG. 2C. FIG. 2C includes the transistors 222a and 222b, and the isolation region 238 between the transistors 222a and 222b. FIG. 2C further includes a third transistor 222c and another portion of the pair of isolation regions 240a and 240b from FIG. 2B, where the portions shown in FIG. 2C are on either side of the transistor 222c.

Example CFET with Stacked Strain Materials

In the example CFET architecture shown in FIG. 2, the isolation regions 238, 240a, and 240b were each formed from a single isolation material 214. As described above, if the isolation material 214 exerts a force (e.g., a strain force) on the surrounding structures, e.g., on the S/D materials 204 and 208, it may be desirable to use different isolation materials in different layers of the device, e.g., different isolation materials for PMOS and NMOS layers.

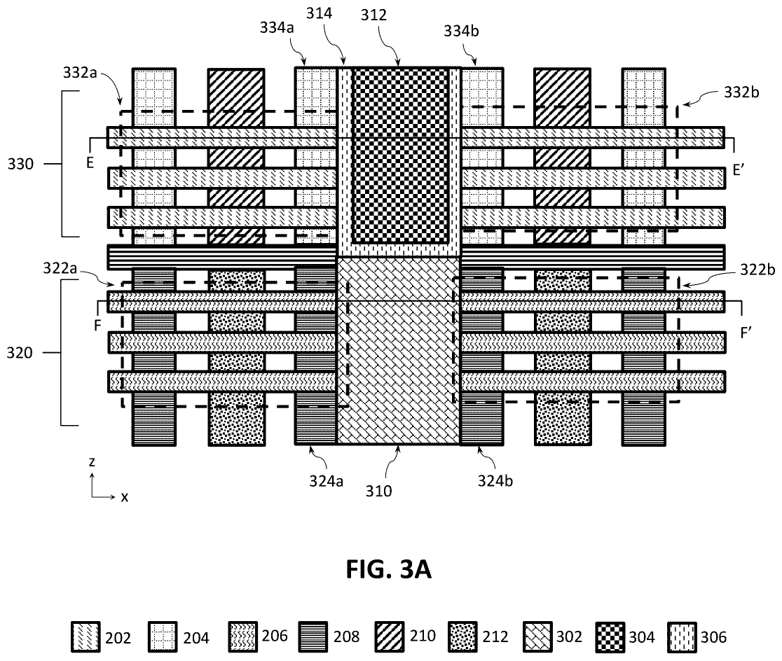

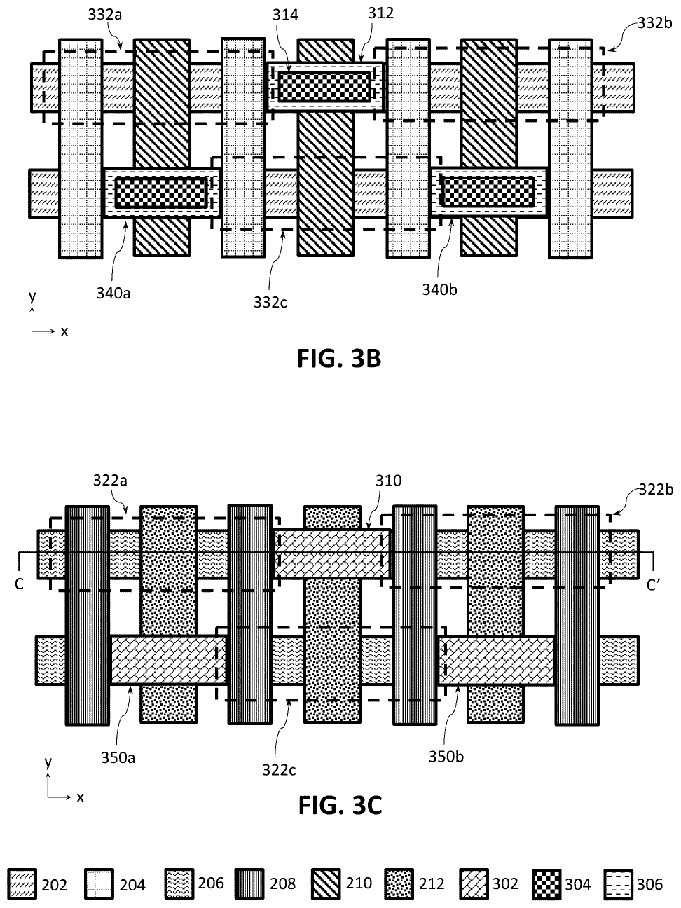

FIG. 3A illustrates a cross-section of a first example CFET device having different strain materials in different layers, according to some embodiments of the present disclosure. FIG. 3B illustrates a cross-section through the second layer 330, and in particular, through the plane EE′ in FIG. 3A. FIG. 3C illustrates a cross-section through the first layer 320, and in particular, through the plane FF′ in FIG. 3A. FIG. 3A includes four transistors, 322a, 322b, 332a, and 332b, arranged in two layers, 320 and 330. The layers 320 and 330 are similar to the layers 220 and 230 in FIG. 2, and the transistors 322a, 322b, 332a, and 332b are similar to the transistors 222a, 222b, 232a, and 232b in FIG. 2.

In FIG. 3, in the FTI area between adjacent transistors (e.g., between transistors 322a and 322b, and between the transistors 332a and 332b), there are different isolation materials at the different layers 320 and 330. Referring to FIG. 3A, in the first layer 320, a first isolation region 310 that includes a first isolation material 302 is between the transistors 322a and 322b. In particular, the isolation region 302 is adjacent to the S/D region 324a of the transistor 322a and the S/D region 324b of the transistor 322b. In this case, the isolation region 302 is abutting (i.e., in contact with) the S/D regions 324a and 324b.

In the second layer 330, a second isolation region 312 that includes a second isolation material 304 is between the transistors 332a and 332b. In particular, the isolation region 312 is adjacent to the S/D region 334a of the transistor 332a and the S/D region 334b of the transistor 332b. In this case, a liner layer 314 that includes a liner material 306 is between the isolation region 312 and the S/D regions 334a, and the liner layer 314 is between the isolation region 312 and the S/D region 324b. A portion of the liner layer 314 is also between the isolation region 312 and the isolation region 310. In some embodiments, a liner layer may be included around the isolation region 302, and/or not included around the isolation region 304. In general, a liner layer may be included around an isolation region 310 or 312 based on the material compositions of the isolation region and/or the adjacent S/D regions. A liner layer may be included to protect a S/D region and/or other materials in the transistor from the liner materials, or vice versa. In some embodiments, the liner material 306 may be the same material as the first isolation material 302.

The first isolation region 310 that includes the first isolation material 302 imparts a first type of strain on the S/D regions 324a and 324b, while the second isolation region 312 that includes the second isolation material 304 imparts a second type of strain on the S/D regions 334a and 334b. For example, if the transistors 322 of the first layer 320 are PMOS transistors, the first isolation material 302 may be selected to be a tensile material (e.g., a material that expands, e.g., during a deposition or annealing process). The first isolation material 302, if it is a tensile material, may impart a compressive force on the surrounding S/D regions 324 and/or the nanoribbon channels. If the transistors 332 of the second layer 330 are NMOS transistors, the second isolation material 304 may be a compressive material (e.g., a material that compresses or shrinks, e.g., during a deposition or annealing process). The second isolation material 304, if it is a compressive material, may impart a tensile strain on the surrounding S/D regions 334 and/or the nanoribbon channels. As another example, if the transistors 322 of the first layer 320 are NMOS transistors, the first isolation material 302 may be a compressive material selected to provide a tensile strain on the surrounding S/D regions 324 and/or nanoribbon channels. If the transistors 332 of the second layer 330 are PMOS transistors, the second isolation material 304 may be a tensile or expansive material selected to provide a compressive strain on the surrounding S/D regions 334 and/or nanoribbon channels.

The isolation material 302, isolation material 304, and liner material 306 may include different dielectric materials, such as oxides (e.g., aluminum oxide, hafnium oxide, silicon oxide, etc.) or nitrides (e.g., silicon nitride). The isolation material 302 may have a different material composition from the isolation material 304. For example, in a PMOS layer, the isolation material may include nitrogen (e.g., silicon nitride or another nitride), and in an NMOS layer, the isolation material may include oxygen (e.g., an oxide). Alternatively or in addition, a fabrication process for the isolation material 302 may be different from a fabrication process for the isolation material 304 and/or the liner material 306. For example, different annealing temperatures may provide different densities, where the strain type is based on the density of the isolation material. As another example, to increase the density of an isolation material, an implantation process may be performed in an isolation region, e.g., to implant boron or another material into the isolation material.

During fabrication, the first isolation material 302 may be deposited in a FTI area between the S/D regions 324a and 324b. The first isolation material 302 be deposited within the full FTI region, and then recessed to remove the first isolation material in the second layer 330, leaving the first isolation region 310. A thin layer of the liner material 306 is deposited to form the liner layer 314, and then the second isolation material 304 is deposited over the liner layer 314 to form the second isolation region 312.

While one set of stacked isolation regions 310 and 312 are illustrated in FIG. 3A, additional stacked isolation regions may be included in different parts of the device. For example, as illustrated in FIGS. 3B and 3C, stacked isolation regions may be present on either side of a transistor. As one example, referring to FIGS. 3B and 3C, in the first layer 320 illustrated in cross-section FIG. 3C, isolation regions 350a and 350b including the first isolation material 302 are on either side of the transistor 322c, e.g., the isolation region 350a is adjacent to a source region of the transistor 322c, and the isolation region 350b is adjacent to a drain region of the transistor 322c. In the second layer 330 illustrated in cross-section in FIG. 3B, isolation regions 340a and 340b including the second isolation material 304 and the liner material 306 are on either side of the transistor 332c, e.g., the isolation region 340a is adjacent to a source region of the transistor 332c, and the isolation region 340b is adjacent to a drain region of the transistor 332c. The isolation regions 340a and 340b are stacked over the isolation regions 350a and 350b, respectively.

While the example of FIG. 3 illustrates GAA transistors, e.g., nanoribbon transistors with three nanoribbons, in other examples, the transistors 322 and 332 may have different architectures. For example, the transistors 322 and 332 may be nanoribbon or nanowire transistors with more or fewer nanoribbons or nanowires. As another example, the transistors 322 and 332 may be FinFETs, as described above with respect to FIG. 1. As another example, the transistors 322 and 332 may be planar transistors.

Example CFET with Stacked Strain Materials

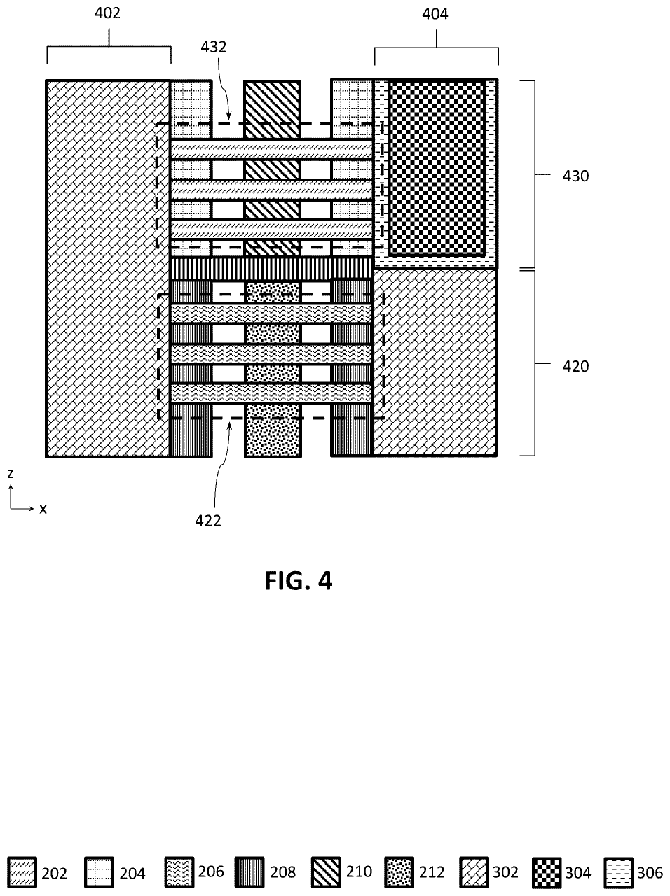

FIG. 4 illustrates a cross-section of a second example CFET device having different strain materials in different layers, according to some embodiments of the present disclosure. FIG. 4 depicts a pair of stacked transistors 422 and 432 and isolation regions 402 and 404 on either side of the stacked transistors 422 and 432, where the transistor 422 is in a first layer 420, and the transistor 432 is in a second layer 430. The transistor 422 is similar to the transistors 222 and 322 of FIGS. 2 and 3, and the transistor 432 is similar to the transistors 232 and 332 of FIGS. 2 and 3.

In this example, the isolation region 404 is a stacked isolation region that is similar to the stack of isolation regions 310 and 312 of FIG. 3, with the liner material 306 around the isolation region 312. Unlike in FIG. 3, where each stack of isolation regions was similar (e.g., as shown in FIGS. 3B and 3C), the isolation region 402 is different from the isolation region 404. In this example, while the isolation region 404 includes a stack with different materials in different layers (i.e., the isolation material 302 in the layer 420, and the isolation material 304 and liner material 306 in the layer 430), the isolation region 402 includes the isolation material 302 in both the first layer 420 and the second layer 430. As noted above, it may be advantageous to provide different types of strain on source regions and drain regions. Asymmetrical strains on sources and drains can be used to increase the threshold voltage at the source, and lower the threshold voltage at the drain. A higher threshold voltage on the source may improve injection velocity, while a lower threshold voltage on the drain may reduce the electric field and mitigate short-channel effects, e.g., reducing subthreshold leakage current and providing more consistent transistor behavior.

During fabrication, the first isolation material 302 may be deposited in the FTI areas, up to the top of the second layer 430. A lithographic process may then be performed to mask a portion of the FTI areas, e.g., the region 402, and expose another portion of the FTI areas, e.g., the region 404. For example, the FTI areas adjacent to drains may be exposed while the FTI areas adjacent to sources are masked, or vice versa. The exposed FTI areas are then recessed to remove the first isolation material in the second layer 430. If a liner material 306 is used, a thin layer of the liner material 306 is deposited to form a liner layer, and then the second isolation material 304 is deposited over the liner layer.

While FIG. 4 illustrates a single stack of transistors 422 and 432, it should be understood that a device may have additional similar transistors and isolation regions. For example, the layer 420 may include additional transistors on one or both sides of the transistor 422, where the isolation material 302 is adjacent to the sources and drains of the additional transistors. Likewise, the layer 430 may include additional transistors on one or both sides of the transistor 422, where the additional transistors may be stacked over additional transistors in the layer 420, and each of the additional transistors have the isolation material 302 adjacent to one S/D region, and each of the additional transistors have the isolation material 304 adjacent to the other S/D region.

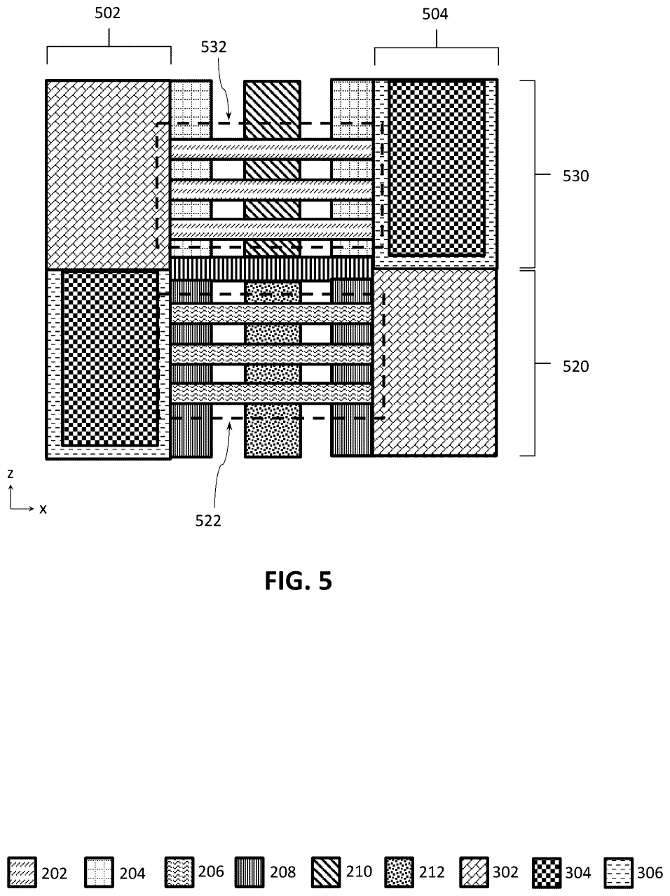

FIG. 5 illustrates a cross-section of a third example CFET device having different strain materials in different layers, according to some embodiments of the present disclosure. As described above, FIG. 4 has a single isolation material 302 across the first layer 420, applying a single type of strain to both sources and drains in this layer 420. In another embodiment, both the first layer 420 and the second layer 430 may have different types of isolation regions with different strains on the sources and drains. An example of this is shown in FIG. 5.

FIG. 5 depicts a pair of stacked transistors 522 and 532 and isolation regions 502 and 504 on either side of the stacked transistors 522 and 532, where the transistor 522 is in a first layer 520, and the transistor 532 is in a second layer 530. The transistor 522 is similar to the transistors 222, 322, and 422 of FIGS. 2-4, and the transistor 532 is similar to the transistors 232, 332, and 432 of FIGS. 2-4.

In this example, the isolation region 504 is a stacked isolation region that is similar to the stacked isolation region 404 of FIG. 4. Unlike FIG. 3, where isolation region 402 was a uniform isolation region that applies the same strain to adjacent S/D regions in both the layer 420 and the layer 430, the isolation region 502 is a stacked isolation region, where the upper and lower materials are swapped with respect to the isolation region 504. For example, in the layer 520, the lower portion of the stacked isolation region 502 may apply a compressive strain, while the lower portion of the stacked isolation region 504 may apply a tensile strain. In the layer 530, the upper portion of the stacked isolation region 502 may apply a tensile strain, while the upper portion of the stacked isolation region 504 may apply a compressive strain. Additional lithographic processes are used to selectively mask and deposit the isolation materials in the respective positions to achieve the design shown in FIG. 5.

While FIG. 5 illustrates a single stack of transistors 522 and 532, it should be understood that a device may have additional similar transistors and isolation regions. For example, the layer 520 may include additional transistors on one or both sides of the transistor 522, where each of the additional transistors have the isolation material 302 on one S/D region, and each of the additional transistors have the isolation material 304 on the other S/D region. Likewise, the layer 530 may include additional transistors on one or both sides of the transistor 522, where the additional transistors may be stacked over additional transistors in the layer 520, and each of the additional transistors have the isolation material 304 adjacent to one S/D region (and over a region of isolation material 302 in the layer 520), each of the additional transistors have the isolation material 302 adjacent to the other S/D region (and over a region of the isolation material 304 in the layer 520).

While the examples of FIGS. 4 and 5 illustrates GAA transistors, e.g., nanoribbon transistors with three nanoribbons, in other examples, any of the transistors 422, 432, 522, and 532 may have different architectures, e.g., nanoribbon or nanowire transistors with more or fewer nanoribbons or nanowires, FinFETs, or planar transistors.

### Example Electronic Devices

The stacked transistors and strain materials described herein may be included in any suitable electronic device. FIGS. 6-9 illustrate various examples of devices and components that may include any of the stacked transistors and strain materials described herein.

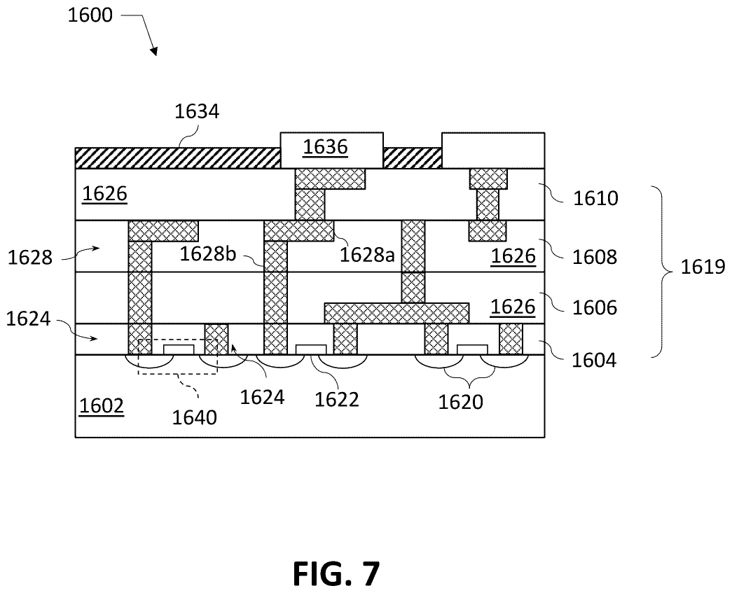

FIGS. 6A and 6B are top views of a wafer and dies that include stacked transistors and strain materials as described herein in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1-5, or any further embodiments of the IC structures described herein). After the fabrication of the semiconductor product is complete (e.g., after manufacture of one or more IC structures with stacked transistors and strain materials as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include stacked transistors and strain materials as described herein may take the form of the wafer 1500 (e.g., not singulated) or the form of the die 1502 (e.g., singulated). The die 1502 may include one or more transistors (e.g., one or more of the transistors 1640 of FIG. 7, discussed below) and/or supporting circuitry to route electrical signals to the transistors, as well as any other IC components. In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 10) or other logic that is configured to store information in the memory devices or execute instructions stored in the memory array.

FIG. 7 is a cross-sectional side view of an IC device 1600 that may include stacked transistors and strain materials as described herein. The IC device 1600 may be formed on a substrate 1602 (e.g., the wafer 1500 of FIG. 6A) and may be included in a die (e.g., the die 1502 of FIG. 6B). The substrate 1602 may be any substrate as described herein. The substrate 1602 may be part of a singulated die (e.g., the dies 1502 of FIG. 6B) or a wafer (e.g., the wafer 1500 of FIG. 6A).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 7 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 7). Although a particular number of interconnect layers 1606-1610 is depicted in FIG. 7, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 7. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 7. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

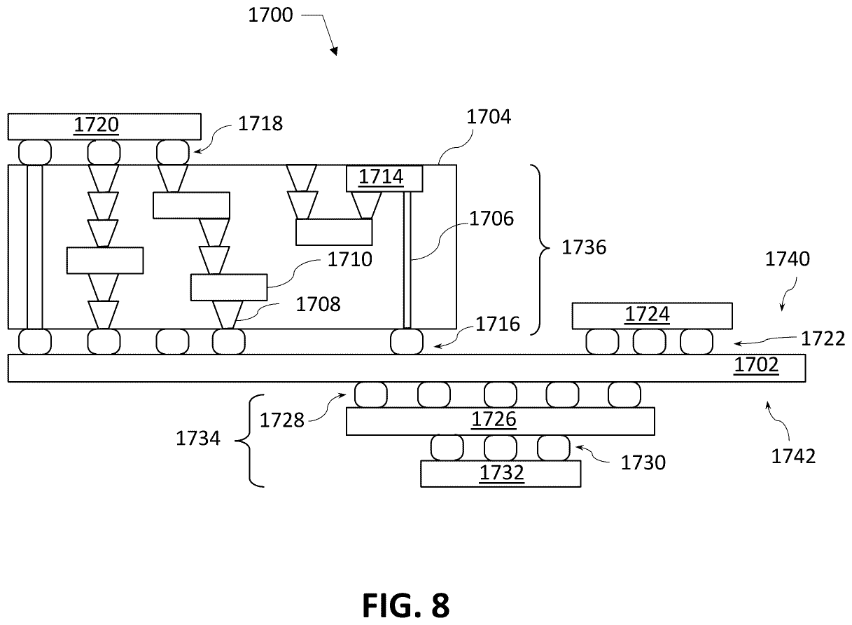

FIG. 8 is a cross-sectional side view of an IC device assembly 1700 that may include components having or being associated with (e.g., being electrically connected by means of) stacked transistors and strain materials as described herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include any of the stacked transistors and strain materials as described herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 8 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 8), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 8, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 6B), an IC device (e.g., the IC device 1600 of FIG. 7), or any other suitable component. In some embodiments, the IC package 1720 may include devices including stacked transistors and strain materials as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 8, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 8 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

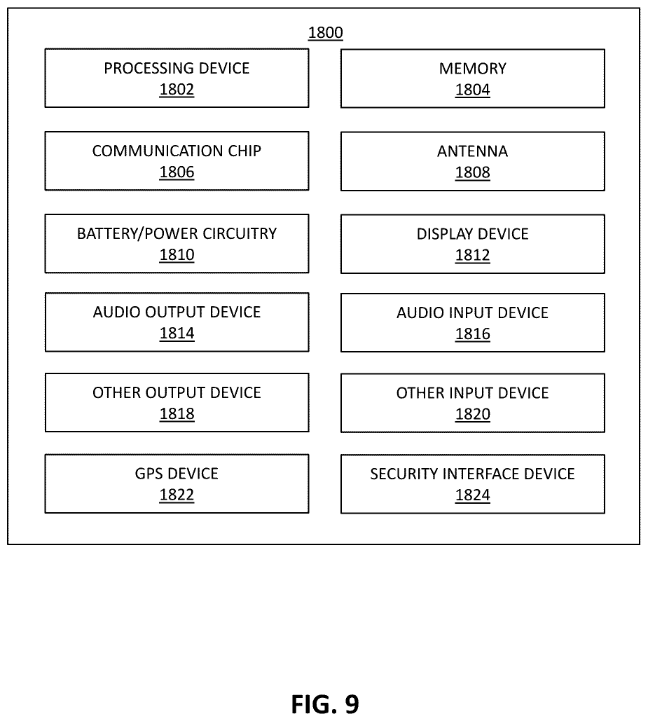

FIG. 9 is a block diagram of an example computing device 1800 that may include one or more components including stacked transistors and strain materials as described herein. For example, any suitable ones of the components of the computing device 1800 may include a die (e.g., the die 1502 of FIG. 6B) having stacked transistors and strain materials as described herein. Any one or more of the components of the computing device 1800 may include, or be included in, an IC device 1600 (FIG. 7). Any one or more of the components of the computing device 1800 may include, or be included in, an IC device assembly 1700 (FIG. 8).

A number of components are illustrated in FIG. 9 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 9, but the computing device 1800 may include interface circuitry for coupling to the one or more components. For example, the computing device 1800 may not include a display device 1806, but may include display device interface circuitry (e.g., a connector and driver circuitry) to which a display device 1806 may be coupled. In another set of examples, the computing device 1800 may not include an audio input device 1824 or an audio output device 1808 but may include audio input or output device interface circuitry (e.g., connectors and supporting circuitry) to which an audio input device 1824 or audio output device 1808 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the computing device 1800 may include a communication chip 1812 (e.g., one or more communication chips). For example, the communication chip 1812 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The computing device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The computing device 1800 may include battery/power circuitry 1814. The battery/power circuitry 1814 may include one or more energy storage devices (e.g., batteries or capacitors) and/or circuitry for coupling components of the computing device 1800 to an energy source separate from the computing device 1800 (e.g., AC line power).

The computing device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1808 (or corresponding interface circuitry, as discussed above). The audio output device 1808 may include any device that generates an audible indicator, such as speakers, headsets, or earbuds, for example.

The computing device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The computing device 1800 may include a GPS device 1818 (or corresponding interface circuitry, as discussed above). The GPS device 1818 may be in communication with a satellite-based system and may receive a location of the computing device 1800, as known in the art.

The computing device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The computing device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### SELECT EXAMPLES

The following paragraphs provide various examples of the embodiments disclosed herein.

Example 1 provides a device including a first layer including a first semiconductor region, the first semiconductor region including a first dopant; and a first isolation region adjacent to the first semiconductor region, the first isolation region including a first isolation material; a second layer over the first layer, the second layer including a second semiconductor region, the second semiconductor region including a second dopant different from the first dopant, the second semiconductor region over the first semiconductor region; and a second isolation region adjacent to the second semiconductor region, the second isolation region including a second isolation material different from the first isolation material.

Example 2 provides the device of example 1, where the first isolation material includes nitrogen.

Example 3 provides the device of example 2, where the second isolation material includes oxygen.

Example 4 provides the device of any of the preceding examples, where the first isolation material has a lower density than the second isolation material.

Example 5 provides the device of any of the preceding examples, where the first isolation material exerts a tensile force on the first semiconductor region, and the second isolation material exerts a compressive force on the second semiconductor region.

Example 6 provides the device of any of the preceding examples, further including a first channel region in the first layer, the first semiconductor region at least partially surrounding the first channel region, and a second channel region in the second layer, the second semiconductor region at least partially surrounding the second channel region.

Example 7 provides the device of example 6, further including in the first layer, a third semiconductor region including the first dopant, the third semiconductor region and the first semiconductor region arranged on opposite ends of the first channel region; and in the second layer, a fourth semiconductor region including the second dopant, the fourth semiconductor region and the second semiconductor region arranged on opposite ends of the second channel region.

Example 8 provides the device of example 7, further including in the first layer, a third isolation region including the first isolation material.

Example 9 provides the device of example 8, further including in the second layer, a fourth isolation region including the second isolation material.

Example 10 provides the device of example 8, further including in the second layer, a fourth isolation region including the first isolation material.

Example 11 provides the device of example 7, further including in the first layer, a third isolation region including the second isolation material; and in the second layer, a fourth isolation region including the first isolation material.

Example 12 provides the device of example 1, where at least one of the first isolation region and the second isolation region includes a liner, and a portion of the liner is between the isolation region and the adjacent semiconductor region.

Example 13 provides a device including a first transistor including a first source region and a first drain region; a first isolation region proximate to the first source region, the first isolation region including a first material; a second isolation region proximate to the first drain region, the second isolation region including the first material; a second transistor including a second source region and a second drain region, the second transistor over the first transistor; a third isolation region proximate to the second source region, the third isolation region including a second material, the third isolation region over the first isolation region; and a fourth isolation region proximate to the second drain region, the fourth isolation region including the second material, the fourth isolation region over the second isolation region.

Example 14 provides the device of example 13, where the first transistor and the second transistor each include at least one nanoribbon.

Example 15 provides the device of example 13, where the first transistor and the second transistor each include a fin-shaped channel region.

Example 16 provides the device of example 13, where the third isolation region and the fourth isolation region each include a liner material, the liner material between the respective isolation region and the respective transistor.

Example 17 provides the device of example 13, where the first isolation region and the third isolation region are arranged along a first gate line.

Example 18 provides the device of example 17, where the second isolation region and the fourth isolation region are arranged along a second gate line, the second gate line extending in parallel to the first gate line.

Example 19 provides a device including a first transistor including a first source region and a first drain region; a first isolation region adjacent to the first source region; a second isolation region adjacent to the first drain region; a second transistor including a second source region and a second drain region, the second transistor over the first transistor; a third isolation region adjacent to the second source region, the third isolation region including first material, the third isolation region over the first isolation region; and a fourth isolation region adjacent to the second drain region, the fourth isolation region including a second material, the fourth isolation region over the second isolation region.

Example 20 provides the device of example 19, where the first isolation region and the second isolation region each include the first material.

Example 21 provides the device of example 19, where the first isolation region includes the second material, and the second isolation region includes the first material.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A device comprising:
a first layer comprising:
a first semiconductor region, the first semiconductor region comprising a first dopant; and
a first isolation region adjacent to the first semiconductor region, the first isolation region comprising a first isolation material;
a second layer over the first layer, the second layer comprising:
a second semiconductor region, the second semiconductor region comprising a second dopant different from the first dopant, the second semiconductor region over the first semiconductor region; and
a second isolation region adjacent to the second semiconductor region, the second isolation region comprising a second isolation material different from the first isolation material.

2. The device of claim 1, wherein the first isolation material comprises nitrogen.

3. The device of claim 2, wherein the second isolation material comprises oxygen.

4. The device of claim 1, wherein the first isolation material has a lower density than the second isolation material.

5. The device of claim 1, wherein the first isolation material exerts a tensile force on the first semiconductor region, and the second isolation material exerts a compressive force on the second semiconductor region.

6. The device of claim 1, further comprising a first channel region in the first layer, the first semiconductor region at least partially surrounding the first channel region, and a second channel region in the second layer, the second semiconductor region at least partially surrounding the second channel region.

7. The device of claim 6, further comprising:
in the first layer, a third semiconductor region comprising the first dopant, the third semiconductor region and the first semiconductor region arranged on opposite ends of the first channel region; and
in the second layer, a fourth semiconductor region comprising the second dopant, the fourth semiconductor region and the second semiconductor region arranged on opposite ends of the second channel region.

8. The device of claim 7, further comprising:
in the first layer, a third isolation region comprising the first isolation material.

9. The device of claim 8, further comprising:
in the second layer, a fourth isolation region comprising the second isolation material.

10. The device of claim 8, further comprising:
in the second layer, a fourth isolation region comprising the first isolation material.

11. The device of claim 7, further comprising:
in the first layer, a third isolation region comprising the second isolation material; and
in the second layer, a fourth isolation region comprising the first isolation material.

12. The device of claim 1, wherein at least one of the first isolation region and the second isolation region comprises a liner, and a portion of the liner is between the isolation region and the adjacent semiconductor region.

13. A device comprising:
a first transistor comprising a first source region and a first drain region;
a first isolation region proximate to the first source region, the first isolation region comprising a first material;
a second isolation region proximate to the first drain region, the second isolation region comprising the first material;
a second transistor comprising a second source region and a second drain region, the second transistor over the first transistor;
a third isolation region proximate to the second source region, the third isolation region comprising a second material, the third isolation region over the first isolation region; and
a fourth isolation region proximate to the second drain region, the fourth isolation region comprising the second material, the fourth isolation region over the second isolation region.

14. The device of claim 13, wherein the first transistor and the second transistor each comprise at least one nanoribbon.

15. The device of claim 13, wherein the first transistor and the second transistor each comprise a fin-shaped channel region.

16. The device of claim 13, wherein the third isolation region and the fourth isolation region each comprise a liner material, the liner material between the respective isolation region and the respective transistor.

17. The device of claim 13, wherein the first isolation region and the third isolation region are arranged along a first gate line, and the second isolation region and the fourth isolation region are arranged along a second gate line, the second gate line extending in parallel to the first gate line.

18. A device comprising:
a first transistor comprising a first source region and a first drain region;
a first isolation region adjacent to the first source region;
a second isolation region adjacent to the first drain region;
a second transistor comprising a second source region and a second drain region, the second transistor over the first transistor;
a third isolation region adjacent to the second source region, the third isolation region comprising first material, the third isolation region over the first isolation region; and
a fourth isolation region adjacent to the second drain region, the fourth isolation region comprising a second material, the fourth isolation region over the second isolation region.

19. The device of claim 18, wherein the first isolation region and the second isolation region each comprise the first material.

20. The device of claim 18, wherein the first isolation region comprises the second material, and the second isolation region comprises the first material.
